(19) United States
(12) Patent Application Publication
(10) Pub. No.: US 2010/0068652 A1
(43) Pub. Date: Mar. 18, 2010

(54) SEMICONDUCTOR DEVICE MANUFACTURING METHOD

(76) Inventor: Kazuhiro TAKAHATA, Kanagawa (JP)

Correspondence Address: FINNEGAN, HENDERSON, FARABOW, GARRETT & DUNNER;LLP, 901 NEW YORK AVENUE, NW, WASHINGTON, DC, 20001-4413, US

(21) Appl. No.: 12/552,056

(22) Filed: Sep. 1, 2009

(30) Foreign Application Priority Data
Sep. 17, 2008 (JP) 2008-238004

(51) Int. Cl. G03F 7/20

(52) U.S. Cl. 430/311

(57) ABSTRACT

To include transferring simultaneously by lithography a first region from a position opposed between a first constituent member and a second constituent member in a longitudinal direction of a third constituent member to the end of a side of the first constituent member and a first mask pattern for forming the first constituent member, onto a semiconductor substrate, transferring simultaneously by lithography a second region including regions other than the first region out of the third constituent member and a second mask pattern for forming the second constituent member, onto the semiconductor substrate, and forming the first constituent member, the second constituent member, and the third constituent member on the semiconductor substrate by using the first and second mask patterns.

### CROSS-REFERENCE TO RELATED APPLICATIONS

This application is based upon and claims the benefit of priority from the prior Japanese Patent Application No. 2008-238004, filed on Sep. 17, 2008; the entire contents of which are incorporated herein by reference.

### BACKGROUND OF THE INVENTION

1. Field of the Invention

The present invention relates to a semiconductor device manufacturing method.

2. Description of the Related Art

With the progress of area reduction and downsizing of a semiconductor device, a highly-integrated static random access memory (SRAM) has a shortened length between gate electrodes adjacent in a longitudinal direction of the gate electrode. Recently, the demanded length has exceeded the resolution limit of a photolithography technique. Even so, as disclosed in Japanese Patent Application Laid-open No. 2004-356469, for example, a further shortened length between gate electrodes to achieve area reduction and downsizing of semiconductor devices has been required.

A contact is formed between gate electrodes adjacent in a lateral direction of the gate electrode. In this case, in order that the gate electrode and the contact are not short-circuited, positions of contact holes at the time of forming the contact need to be accurately aligned between the gate electrodes. However, to achieve further area reduction and downsizing of semiconductor devices, also in a lateral direction of the gate electrode, shortening of the length between the adjacent gate electrodes has been required. This further shortens a length between the gate electrode and the contact, and it makes alignment of the contact hole more difficult.

Shortening of the length between arrangement patterns described above has been required not only in gate electrodes but also required in wiring layers. Moreover, further shortening of the length between the arrangement patterns has been required.

### BRIEF SUMMARY OF THE INVENTION

One aspect of this invention is to provide a manufacturing method of a semiconductor device including a semiconductor substrate that is formed thereon with: a first constituent member; a second constituent member that is extended to be separated from the first constituent member on an extension of a longitudinal direction of the first constituent member; and a third constituent member that is separated from the first constituent member and the second constituent member in a lateral direction of the first and second constituent members and that is opposed in one portion to the first and second constituent members, the manufacturing method comprising: transferring simultaneously by lithography, a first region from a position opposed between the first and second constituent members in the longitudinal direction to an end of a side of the first constituent member in the longitudinal direction in the third constituent member, and a first mask pattern for forming the first constituent member, onto a semiconductor substrate; transferring simultaneously by lithography a second region including regions other than the first region in the third constituent member and a second mask pattern for forming the second constituent member, onto the semiconductor substrate; and forming the first constituent member, the second constituent member, and the third constituent member on the semiconductor substrate by using the first mask pattern and the second mask pattern.

Another aspect of this invention is to provide a manufacturing method of a semiconductor device including a semiconductor substrate that is formed thereon with: a first constituent member; a second constituent member that is extended to be separated from the first constituent member on an extension of a longitudinal direction of the first constituent member; a third constituent member that is separated from the first constituent member and the second constituent member in a lateral direction of the first and second constituent members and that is opposed in one portion to the first and second constituent members; a first contact arranged to be separated from both the first constituent member and the third constituent member in a region between the first and third constituent members; and a second contact arranged to be separated from both the second constituent member and the third constituent member in a region between the second and third constituent members, the manufacturing method comprising: transferring simultaneously by lithography, a first region from a position opposed between the first and second constituent members in the longitudinal direction to an end of a side of the first constituent member in the longitudinal direction in the third constituent member, and a first mask pattern for forming the first constituent member, onto a semiconductor substrate; transferring simultaneously by lithography a second region including regions other than the first region in the third constituent member and a second mask pattern for forming the second constituent member, onto the semiconductor substrate; forming the first constituent member, the second constituent member, and the third constituent member on the semiconductor substrate by using the first mask pattern and the second mask pattern; forming by lithography a third mask pattern for forming the first contact on the semiconductor substrate by being aligned to the first constituent member and third constituent member; forming by lithography a fourth mask pattern for forming the second contact on the semiconductor substrate by being aligned to the second constituent member and third constituent member; and forming a contact hole for forming the first contact and a contact hole for forming the second contact on the semiconductor substrate by using the third mask pattern and the fourth mask pattern.

Another aspect of this invention is to provide a manufacturing method of a semiconductor device including a semiconductor substrate that is formed thereon with: a first constituent member; a second constituent member that is extended to be separated from the first constituent member on an extension of a longitudinal direction of the first constituent member; and a third constituent member that is separated from the first constituent member and the second constituent member in a lateral direction of the first and second constituent members and that is opposed in one portion to the first and second constituent members, the manufacturing method comprising: transferring simultaneously by lithography, a first region from a position opposed between the first and second constituent members in the longitudinal direction to an end of a side of the second constituent member in the longitudinal direction in the third constituent member, and a first mask pattern for forming the first constituent member, onto a semiconductor substrate; transferring simultaneously by lithography a second region including regions other than the first region in the third constituent member and a second mask pattern for forming the second constituent member, onto the semiconductor substrate; and forming the first constituent member, the second constituent member, and the third constituent member on the semiconductor substrate by using the first mask pattern and the second mask pattern.

### BRIEF DESCRIPTION OF THE DRAWINGS

FIGS. 1A and 1B are schematic diagrams for explaining a configuration of a semiconductor device according to a first embodiment of the present invention;

FIG. 2 is a schematic diagram for explaining a semiconductor device manufacturing method according to the first embodiment;

FIG. 3 is a schematic diagram for explaining the semiconductor device manufacturing method according to the first embodiment;

FIG. 4 is a schematic diagram for explaining the semiconductor device manufacturing method according to the first embodiment;

FIG. 5 is a schematic diagram for explaining the semiconductor device manufacturing method according to the first embodiment;

FIGS. 6A and 6B are schematic diagrams for explaining the semiconductor device manufacturing method according to the first embodiment;

FIGS. 7A and 7B are schematic diagrams for explaining the semiconductor device manufacturing method according to the first embodiment;

FIGS. 8A and 8B are schematic diagrams for explaining the semiconductor device manufacturing method according to the first embodiment;

FIGS. 9A and 9B are schematic diagrams for explaining the semiconductor device manufacturing method according to the first embodiment;

FIGS. 10A and 10B are schematic diagrams for explaining the semiconductor device manufacturing method according to the first embodiment;

FIGS. 11A and 11B are schematic diagrams for explaining the semiconductor device manufacturing method according to the first embodiment;

FIGS. 12A and 12B are schematic diagrams for explaining a semiconductor device manufacturing method according to a second embodiment of the present invention;

FIGS. 13A and 13B are schematic diagrams for explaining the semiconductor device manufacturing method according to the second embodiment;

FIGS. 14A and 14B are schematic diagrams for explaining the semiconductor device manufacturing method according to the second embodiment;

FIGS. 15A and 15B are schematic diagrams for explaining the semiconductor device manufacturing method according to the second embodiment;

FIGS. 16A and 16B are schematic diagrams for explaining the semiconductor device manufacturing method according to the second embodiment;

FIGS. 17A and 17B are schematic diagrams for explaining a gate electrode in a semiconductor device according to a third embodiment of the present invention;

FIG. 18 is a schematic diagram for explaining a manufacturing method of a gate electrode in the semiconductor device according to the third embodiment;

FIG. 19 is a schematic diagram for explaining the manufacturing method of a gate electrode in the semiconductor device according to the third embodiment;

FIGS. 20A and 20B are schematic diagrams for explaining the manufacturing method of a gate electrode in the semiconductor device according to the third embodiment;

FIGS. 21A and 21B are schematic diagrams for explaining the manufacturing method of a gate electrode in the semiconductor device according to the third embodiment;

FIGS. 22A and 22B are schematic diagrams for explaining the manufacturing method of a gate electrode in the semiconductor device according to the third embodiment;

FIGS. 23A and 23B are schematic diagrams for explaining a wire layer in a semiconductor device according to a fourth embodiment of the present invention; and

FIG. 24 is a schematic diagram for explaining a manufacturing method of a wire layer in the semiconductor device according to the fourth embodiment.

### DETAILED DESCRIPTION OF THE INVENTION

Exemplary embodiments of a semiconductor device manufacturing method according to the present invention will be explained below in detail with reference to the accompanying drawings. The present invention is not limited to the descriptions of the following embodiments and various modifications can be appropriately made without departing from the scope of the invention. In the drawings explained below, scales of respective members may be shown differently from those in practice to facilitate understanding, and the same applies to the relationships between drawings. In addition, explanations and illustrations of constituent members not directly relevant to the present invention will be omitted.

### First Embodiment

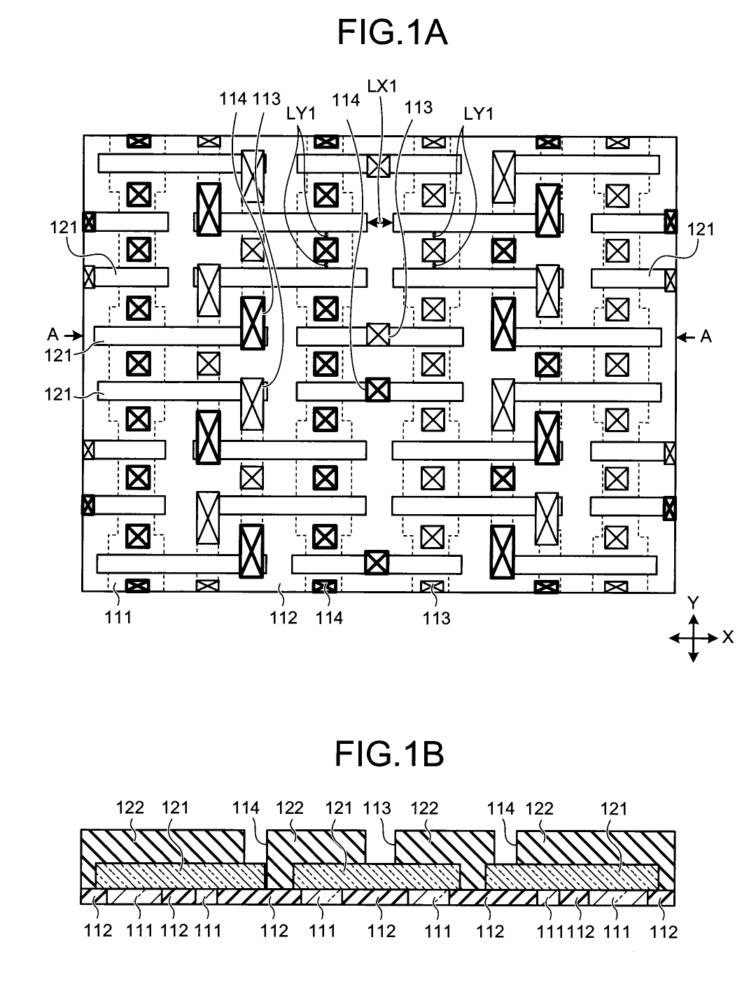

FIGS. 1A and 1B are schematic diagrams for explaining a part of the configuration of a semiconductor device according to a first embodiment of the present invention, that is, a highly-integrated SRAM in which six transistors are point-symmetrically laid out. FIG. 1A is a plan view and FIG. 1B is a cross-sectional view. In the semiconductor device, on a semiconductor substrate, a plurality of transistors (not shown) are arranged in device forming regions (active regions) 111. The device forming region 111 is defined by being surrounded by device isolating regions 112. Within the semiconductor substrate in each device forming region 111, two impurity diffusion layers, which serve as a source and a drain of a transistor, are arranged (not shown).

On the semiconductor substrate between the two impurity diffusion layers, a plurality of substantially rectangular gate electrodes 121 made of polysilicon are arranged substantially parallel via a gate insulating film (not shown) made of a silicon oxide film, and interlayer insulating films 122 are arranged over the entire surface of the semiconductor substrate so that the gate electrodes 121 are covered. Within each interlayer insulating film 122, a plurality of contact holes A 113 and contact holes B 114 each of which conducts to the impurity diffusion layer or the gate electrode 121 are arranged. FIGS. 1A and 1B depict a state that the contact holes A 113 and the contact holes B 114 are formed in the interlayer insulating film 122. FIG. 1A depicts a state that the interlayer insulating film 122 is provided in a transparent manner.

In the first embodiment, the gate electrodes 121 adjacent in a longitudinal direction of each gate electrodes 121 (an X direction in FIG. 1A. Hereinafter, “longitudinal direction”) are arranged on the substantially same line. A length LX1 between the gate electrodes 121 adjacent in the longitudinal direction (the X direction in FIG. 1A) is set to a very short length that exceeds a resolution limit of a photolithography technique, making it very difficult to form its configuration.

Between the gate electrodes 121 adjacent in a lateral direction of each gate electrode 121 (a Y direction in FIG. 1A. Hereinafter, “lateral direction”), the contact hole A 113 or the contact hole B 114 is formed. A length between the gate electrode 121 and the contact hole A 113, and a length LX1 between the gate electrode 121 and the contact hole B 114 are set to a very short length that exceeds a resolution limit of a photolithography technique. This makes it very difficult to configure to form the contact hole A 113 and the contact hole B 114 at predetermined positions so that the contact formed by using the contact hole A 113 or the contact hole B 114 and the gate electrodes 121 are not short-circuited. When a length between members in an in-plane direction of a semiconductor substrate is thus set to a short length that exceeds a resolution limit of a photolithography technique, the SRAM according to the first embodiment leads to high integration of transistors, thereby realizing an SRAM with a reduced area.

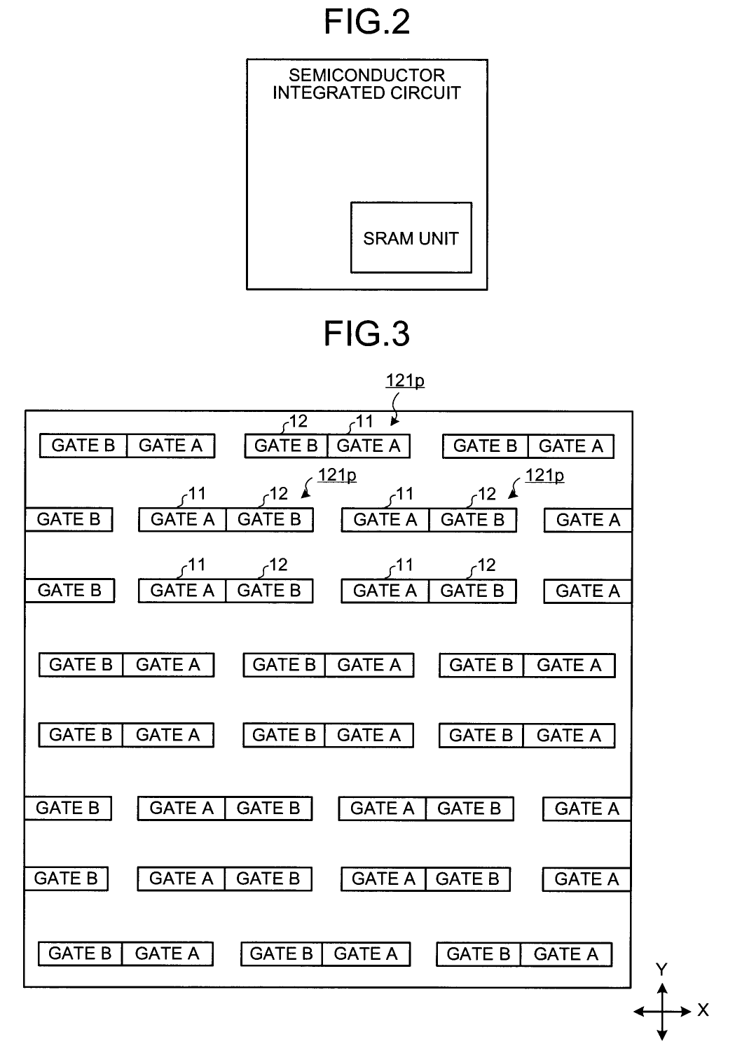

A highly-integrated SRAM manufacturing method according to the first embodiment is explained below with reference to FIGS. 2 to 11B. FIG. 2 to FIG. 11B are schematic diagrams for explaining the highly-integrated SRAM manufacturing method according to the first embodiment, where each drawing denoted with A is a plan view, and each drawing denoted with B is a cross-sectional view along a line A-A in each corresponding drawing denoted with A. Explanations of the formation of the gate insulating film will be omitted. First, as shown in FIG. 2, a design layout of an SRAM unit is extracted from a design layout of a semiconductor device, and rectangular patterns 121p of the gate electrodes 121 are extracted from the extracted design layout.

Next, the rectangular pattern 121p of each of the extracted gate electrodes 121 is divided into two substantially rectangular patterns, that is, a substantially rectangular gate pattern A (hereinafter, “gate A”) 11 and gate pattern B (hereinafter, “gate B”) 12. These patterns A and B are divided along a borderline or certain intermediate position of the longitudinal direction (an X direction in FIG. 3) of each rectangular pattern, as shown in FIG. 3. In this way, the design layout of the gate electrode 121 is divided into two, that is, the gate A 11 and the gate B 12. In this case, each rectangular pattern is divided into two patterns along the borderline or certain intermediate position of the longitudinal direction of each rectangular pattern, and the borderline, however, can be any position as long as it is between the other two gate electrodes 121 opposed in the lateral direction.

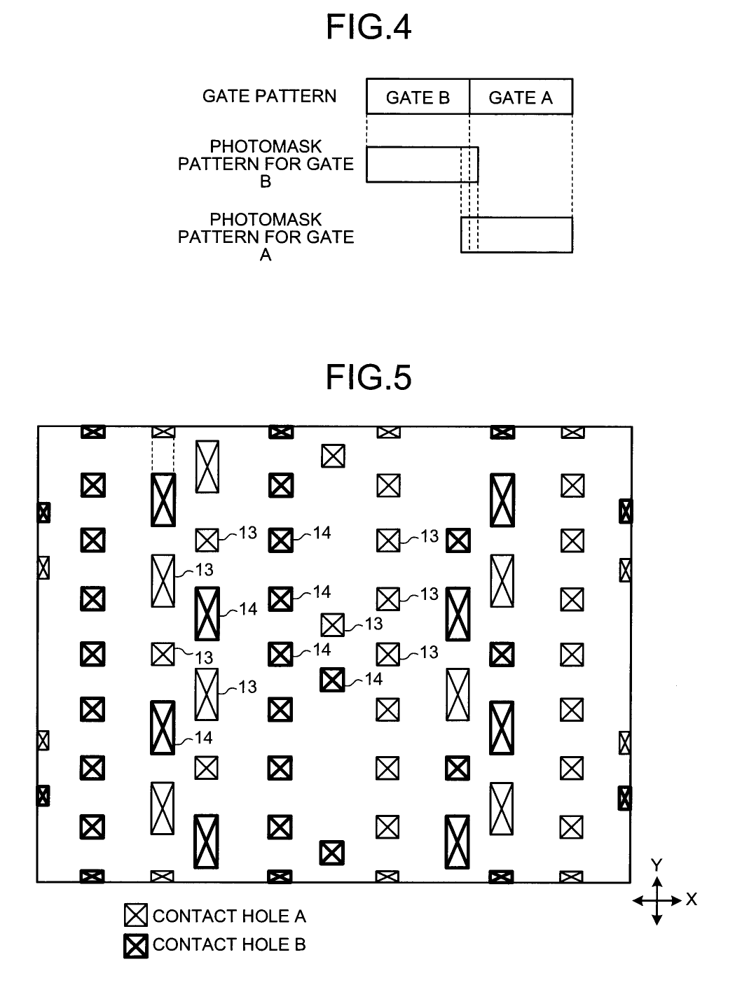

Thereafter, in order that in each of the divided layouts, a pattern according to a design value is formed on the semiconductor substrate, there is manufactured a photomask that is formed with a gate electrode pattern corrected by using optical proximity correction (OPC). That is, two photomasks (a photomask for the gate A and a photomask for the gate B) are manufactured. At this time, the patterns for the gate A and the gate B in the photomasks are so formed that the gate A 11 and the gate B 12 are overlapped each other by several tens of nanometers in the longitudinal direction of the rectangular pattern, as shown in FIG. 4.

Next, from the design layout of the SRAM unit, a design layout of the contact hole is extracted. In the design layout, as shown in FIG. 5, a square-shaped contact hole flanked between the two gates A 11 adjacent in the lateral direction (a Y direction in FIG. 5) is set as a contact hole pattern A 13. A square-shaped contact hole pattern flanked between the two gates B 12 adjacent in the lateral direction (the Y direction in FIG. 5) is set as a contact hole pattern B 14, as shown in FIG. 5. Thereby, the design layout of the contact hole is divided into two, that is, the contact hole pattern A 13 and the contact hole pattern B 14.

Other contact hole patterns are classified into either the contact hole pattern A 13 or the contact hole pattern B 14 depending on a process margin. Thereafter, in order that in each of the divided layouts, a pattern according to a design value is formed on the semiconductor substrate, there is manufactured a photomask that is formed with a contact hole pattern corrected by using OPC or a contact hole pattern added with an unresolved assisting pattern. That is, two photomasks (a photomask for the contact hole pattern A and a photomask for the contact hole pattern B) are manufactured.

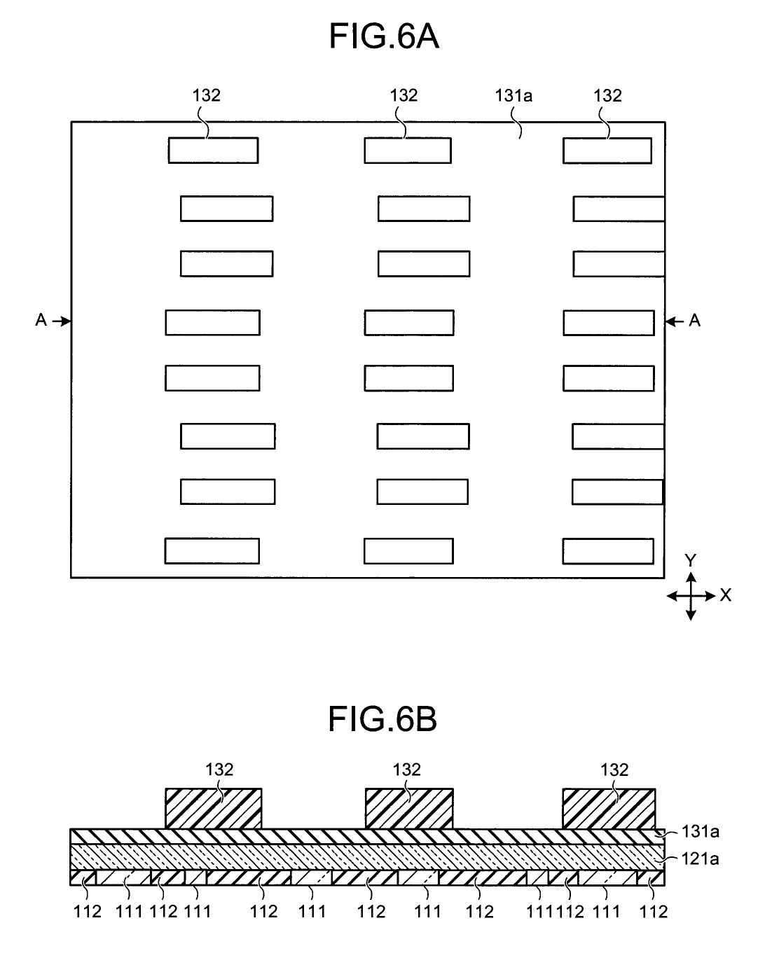

Next, as shown in FIGS. 6A and 6B, on a main surface of the semiconductor substrate formed with the device forming regions 111 defined by being surrounded by the device isolating regions 112, a polysilicon film 121a for forming gate electrodes is formed, and on top of the polysilicon film 121a, a silicon nitride film, for example, is formed as a first hard mask film 131a. By employing photolithography using the photomask for the gate A, a first resist patterns 132 are formed on the first hard mask film 131a, as shown in FIGS. 6A and 6B. Thereby, the first resist patterns 132 are formed at a position corresponding to the gate A 11 on the main surface of the semiconductor substrate. Thereafter, according to need, a process of slimming the first resist pattern 132 is performed by etching.

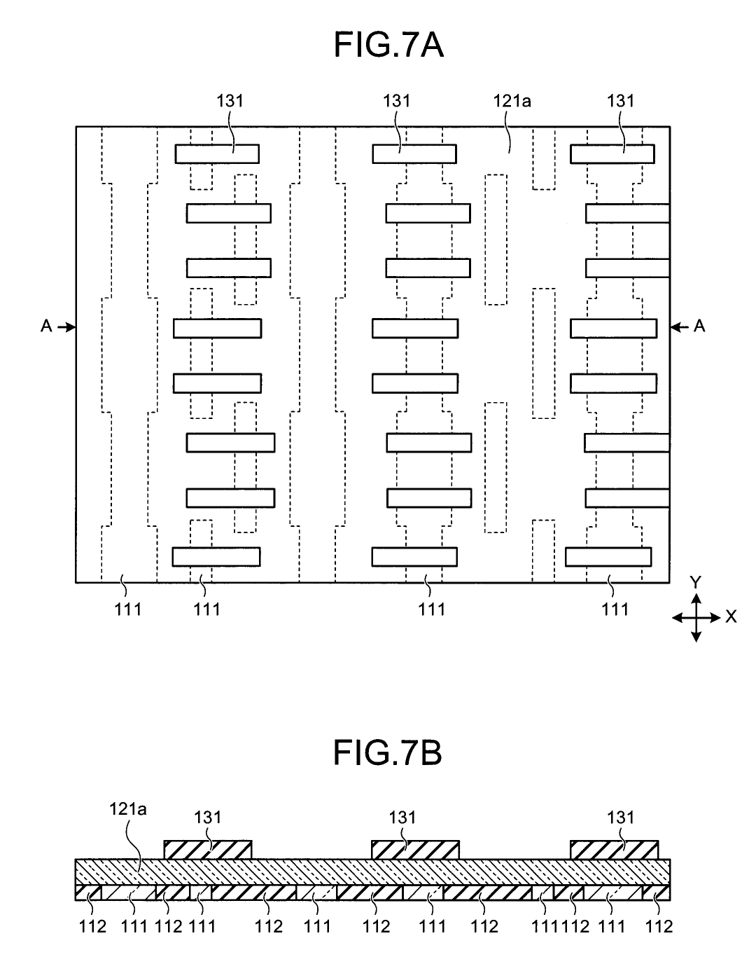

Next, the first resist patterns 132 are used as a mask to etch the first hard mask film 131a, and as shown FIGS. 7A and 7B, the first hard mask patterns 131 are formed on the polysilicon film 121a. Thereby, the first hard mask patterns 131 are formed at a position corresponding to the gates A 11.

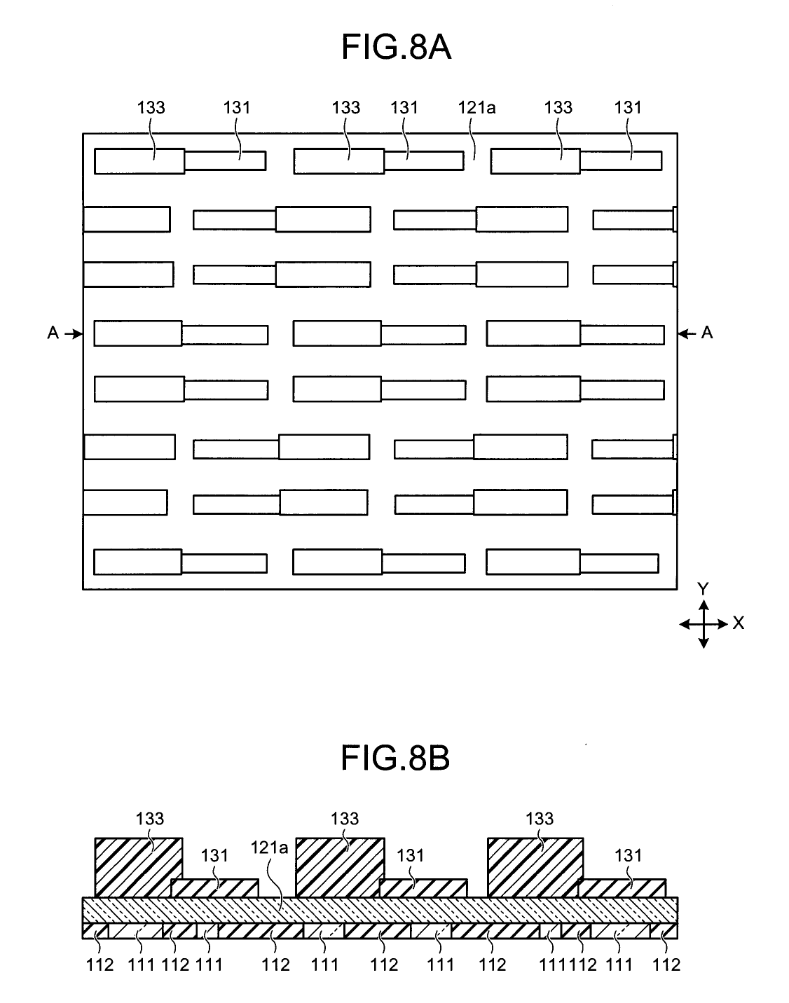

Next, by employing photolithography using the photomask for the gates B, second resist patterns 133 are formed at a position corresponding to the gates B 12, as shown in FIGS. 8A and 8B. The patterns of the photomask for the gates A and the patterns of the photomask for the gates B are so formed that the both patterns are overlapped each other in the longitudinal direction of the rectangular pattern by several tens of nanometers as shown in FIG. 4, and thus the second resist pattern 133 is so formed that one portion thereof is overlapped with the first hard mask pattern 131. The second resist pattern 133 is formed in a region of the rectangular pattern 121p (over the entire region other than a region of at least the first hard mask pattern 131). Thereafter, according to need, a process of slimming the second resist patterns 133 are performed by etching.

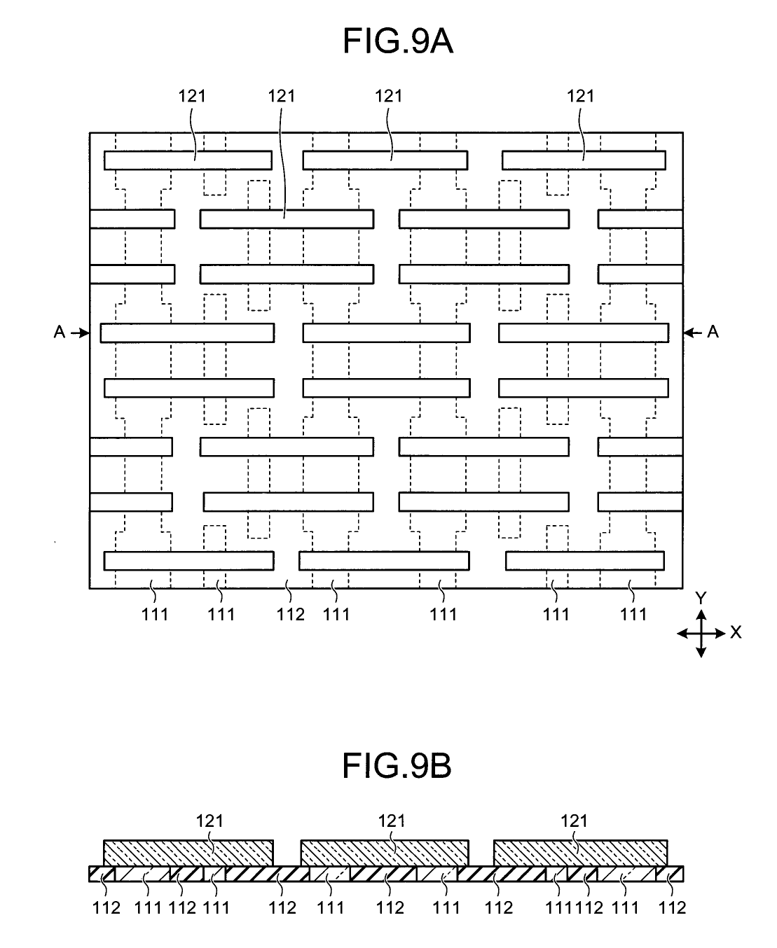

Next, the first hard mask patterns 131 and the second resist patterns 133 are used as a mask to etch the polysilicon film 121a, thereby removing the first hard mask patterns 131 and the second resist patterns 133. As a result, the gate electrodes 121 are formed as shown in FIGS. 9A and 9B.

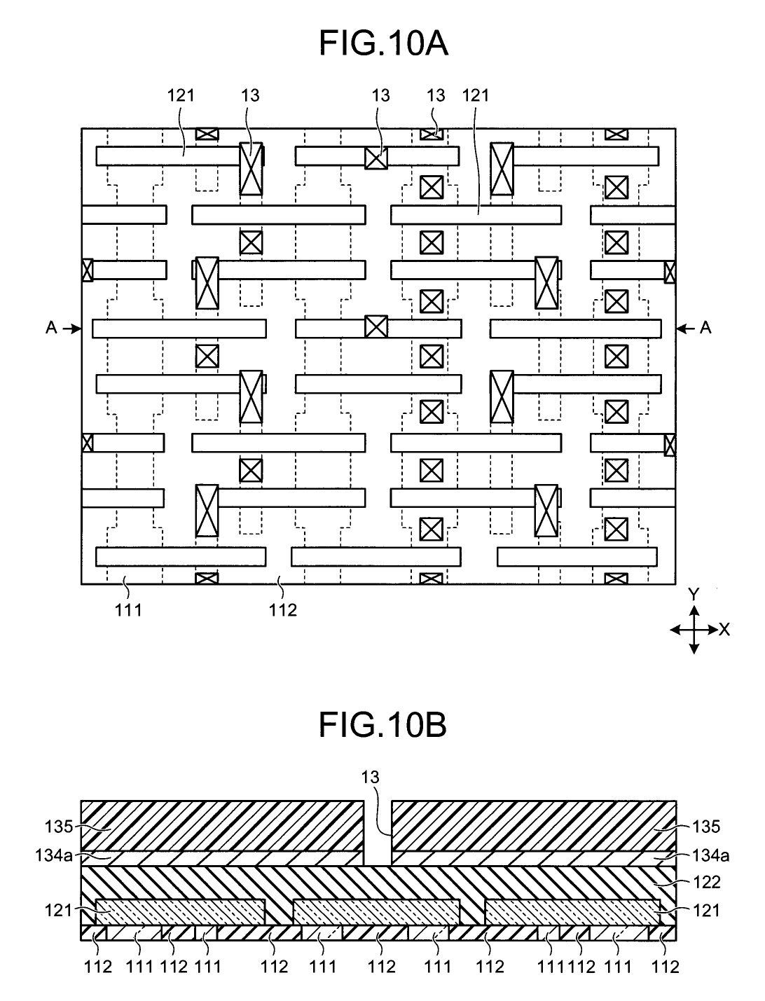

Next, formation of the interlayer insulating film 122 and a second hard mask film 134a on the semiconductor substrate in this order is formed out, as shown in FIGS. 10A and 10B. A third resist film (not shown) is further formed on the semiconductor substrate. By employing photolithography using a photomask for the contact hole patterns A, a third resist patterns 135 are formed as shown in FIGS. 10A and 10B, thereby forming the contact hole patterns A 13.

At this time, the contact hole patterns A 13, which are aligned to the gates A 11, is exposed. That is, the contact hole pattern A 13 is so aligned that one portion thereof is precisely overlapped over the gate A 11 of an underlayer, and the contact hole pattern A 13 are so aligned that another portion thereof is not overlapped in the gate A 11 in a region between the gates A 11 adjacent in the lateral direction. The exposure is performed in this state. Thereafter, as shown in FIGS. 10A and 10B, the third resist patterns 135 are used as a mask to etch the second hard mask film 134a.

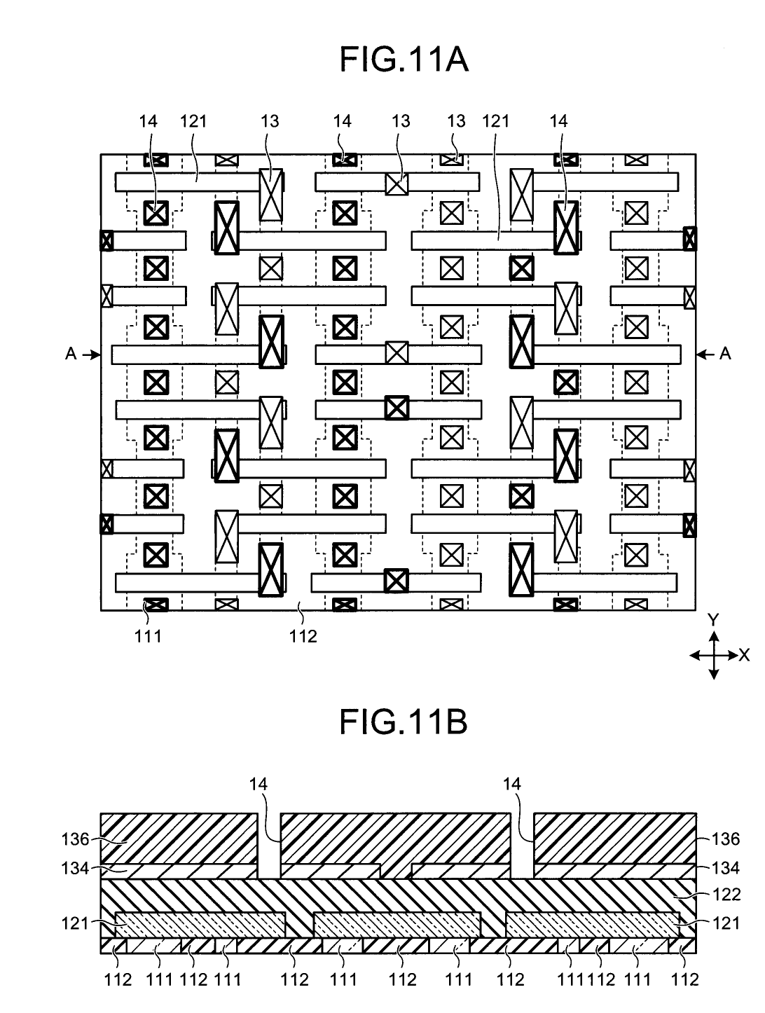

Next, the third resist patterns 135 are removed, and a fourth resist film (not shown) is formed on the semiconductor substrate. By employing photolithography using a photomask for the contact hole patterns B, a fourth resist patterns 136 are formed as shown in FIGS. 11A and 11B, thereby forming the contact hole patterns B 14.

At this time, the contact hole patterns B 14, which are aligned to the gates B 12, is exposed. That is, the contact hole pattern B 14 is so aligned that one portion thereof is precisely overlapped over the gate B 12 of an underlayer, and the contact hole pattern B 14 is so aligned that another portion thereof is not overlapped with the gate B 12 in a region between the gates B 12 adjacent in the lateral direction. In this state, the exposure is performed. Thereafter, as shown in FIGS. 11A and 11B, the fourth resist patterns 136 are used as a mask to etch the second hard mask film 134a, thereby forming second hard mask patterns 134.

The fourth resist patterns 136 are then removed, and the second hard mask patterns 134 are used as a mask to etch the interlayer insulating film 122, thereby forming the contact holes A 113 and the contact holes B 114. As a result, the highly-integrated SRAM according to the first embodiment shown in FIGS. 1A and 1B is formed.

As described above, in the highly-integrated SRAM manufacturing method according to the first embodiment, at the time of forming the etching mask for forming the gate electrodes 121 by using the lithography, the pattern for the gate electrodes 121 are divided into two patterns, that is, the pattern for the gates A 11 and that for the gates B 12, so that the patterns of the same type are not faced to each other at a line end of the pattern. Thereafter, the divided patterns are arranged on two respectively different photomasks, and transferred to the etching mask over two exposing steps. That is, pattern ends of the gate electrodes 121 adjacent in the longitudinal direction are arranged, one pattern after the other, on the different photomasks, and transferred to the etching mask over two exposing steps. Thereby, even when the length LX1 between the gate electrodes 121 adjacent in the longitudinal direction exceeds the resolution limit of a photolithography technique, it is possible to prevent deterioration in the dimensional accuracy which is caused due to the length LX1 at the time of forming the etching mask and which is found in the exposure at a photolithography step, and possible to form a plurality of gate electrodes 121 with a favorable positioning accuracy at a desired position in the longitudinal direction. In the first embodiment, a case that the divided patterns are arranged on the two respectively different photomasks and transferred to the etching mask over the two exposing steps has been described. However, the divided patterns can be separately arranged on a single photomask and transferred to the etching mask over the two exposing steps.

Further, in another highly-integrated SRAM manufacturing method according to the first embodiment, the pattern for the gate electrodes 121 in the regions overlapped in the longitudinal direction are divided, as patterns of the same type, into two, that is, the gate A 11 and the gate B 12. The divided patterns are arranged on the two respectively different photomasks and transferred to the etching mask over the two exposing steps. The contact hole patterns A 13 arranged in a region between the gates A 11 in the lateral direction, which are directly aligned to the gates A 11 in the gate electrodes 121, are exposed. The contact hole patterns B 14 arranged in a region between the gates B 12 in the lateral direction, which are directly aligned to the gates B 12 in the gate electrode 121, are exposed.

Accordingly, the patterns for the contact holes are directly aligned only to the pattern for the adjacent gate electrodes 121, and thus even when the length LY1 between the contact hole and the gate electrode 121 adjacent in the lateral direction exceeds the resolution limit of a photolithography technique, a plurality of contact holes 113 and 114 can be formed at a desired position with a favorable positioning accuracy rather than deteriorating the accuracy of precisely overlapping the gate electrode 121 on the contact hole pattern. Moreover, the patterns for the contact holes are directly aligned only to the patterns for the adjacent gate electrodes 121, and thus, even when the length LY1 between the contact hole and the gate electrode 121 adjacent in the lateral direction or the position of the gate electrodes 121 adjacent in the lateral direction exceeds the accuracy limit of indirect aligning, the contact holes 113 and 114 can be formed at a desired position with a favorable positioning accuracy rather than deteriorating the accuracy of precisely overlapping the gate electrode 121 on the contact hole pattern. The indirect aligning accuracy is an accuracy of aligning the pattern for a first contact hole and the pattern for a first gate electrode in a case that the pattern for the first contact hole is not individually aligned directly to the pattern for the first gate electrode adjacent in the lateral direction and the position of the pattern for the first contact hole is determined according to the alignment between a pattern for the other second contact hole and the pattern for the second gate electrode adjacent to the second contact hole in the lateral direction, for example.

Therefore, in the highly-integrated SRAM manufacturing method according to the first embodiment, the length between the gate electrodes adjacent in the longitudinal direction and the length between the gate electrode and the contact hole are shortened, and at the same time, these members can be formed at a desired position with a favorable positioning accuracy. Thus, area reduction of a semiconductor device can be achieved.

### Second Embodiment

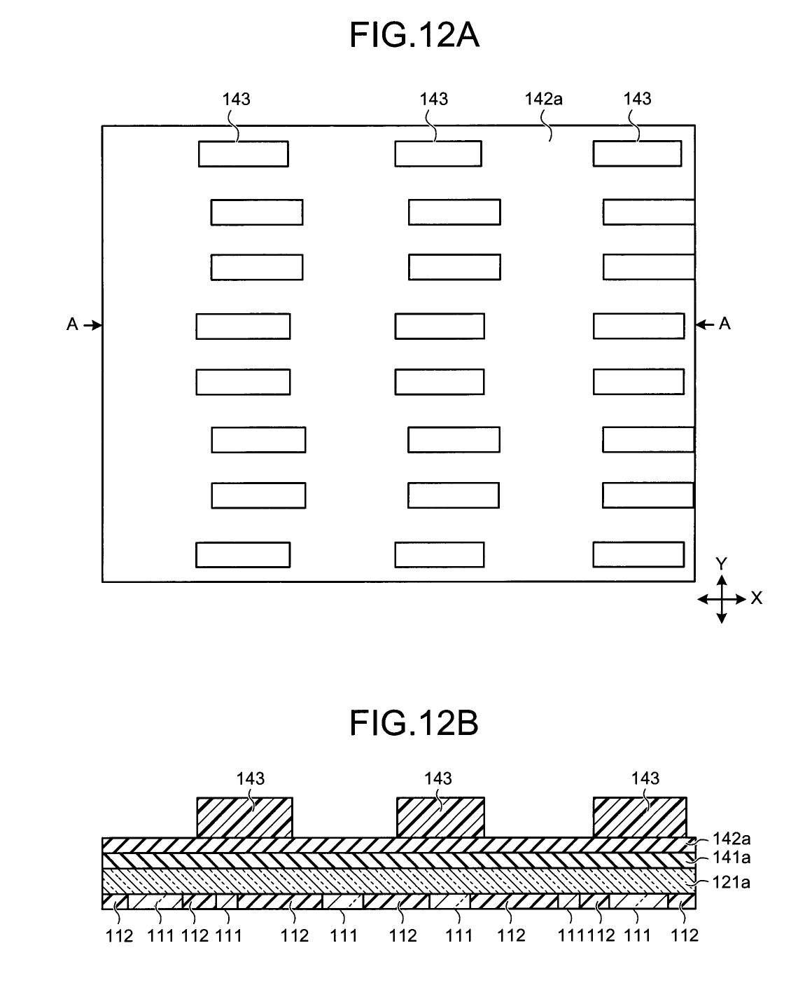

In a second embodiment of the present invention, another manufacturing method of the highly-integrated SRAM of the first embodiment shown in FIG. 1 is described with reference to FIGS. 12A to 16B. FIGS. 12A to 16B are schematic diagrams for explaining a highly-integrated SRAM manufacturing method according to the second embodiment, where each drawing denoted with A is a plan view, and each drawing denoted with B is a cross-sectional view along a line A-A in each corresponding drawing denoted with A. Explanations of the formation of the gate insulating film will be omitted.

First, according to the steps described in the first embodiment with reference to FIGS. 2 to 5, the photomask for the gates A, the photomask for the gates B, the photomask for the contact hole patterns A, and the photomask for the contact hole patterns B are manufactured.

Next, as show in FIGS. 12A and 12B, on a main surface of the semiconductor substrate formed with the device forming regions 111 defined by being surrounded by the device isolating regions 112, the polysilicon film 121a for forming gate electrodes is formed, and on top of the polysilicon film 121a, a silicon nitride film, for example, is formed as a first hard mask film 141a. On top of the first hard mask film 141a, a silicon oxide film, for example, is formed as a second hard mask film 142a. By employing photolithography using the photomask for the gates A, first resist patterns 143 are formed on the second hard mask film 142a, as shown in FIGS. 12A and 12B. Thereby, the first resist patterns 143 are formed at a position corresponding to the gates A 11 on the main surface of the semiconductor substrate. Thereafter, according to need, a process of slimming the first resist patterns 143 are performed by etching.

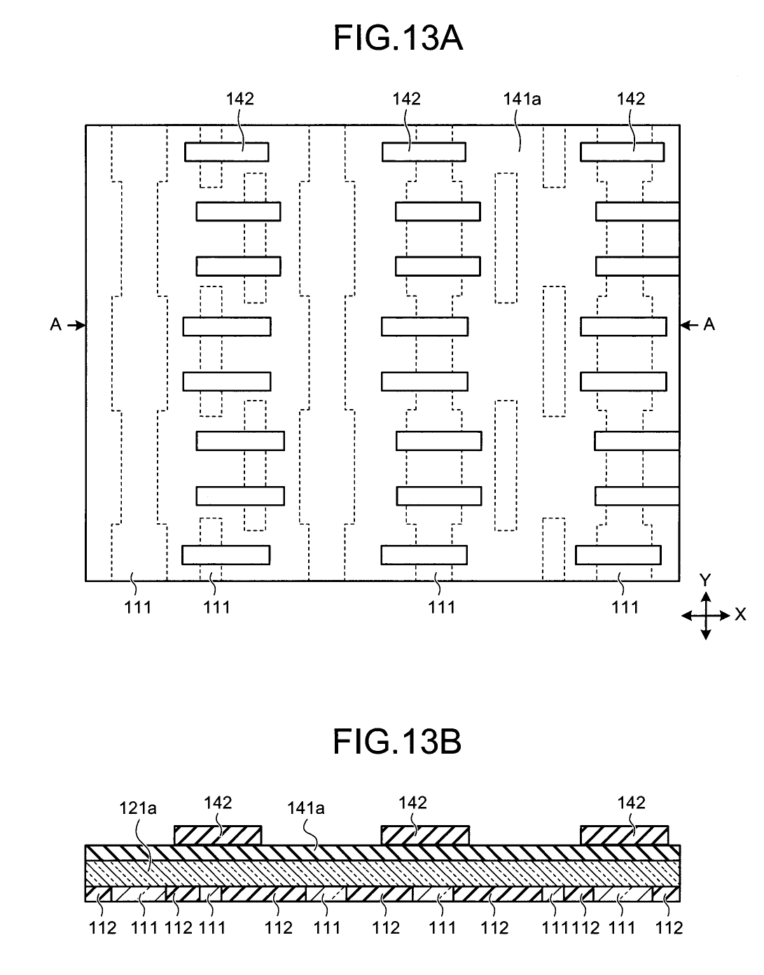

Next, the first resist patterns 143 are used as a mask to etch the second hard mask film 142a, and as shown in FIGS. 13A and 13B, second hard mask patterns 142 are formed on the first hard mask film 141a. Thereby, the second hard mask patterns 142 are formed at a position corresponding to the gates A 11 on the main surface of the semiconductor substrate.

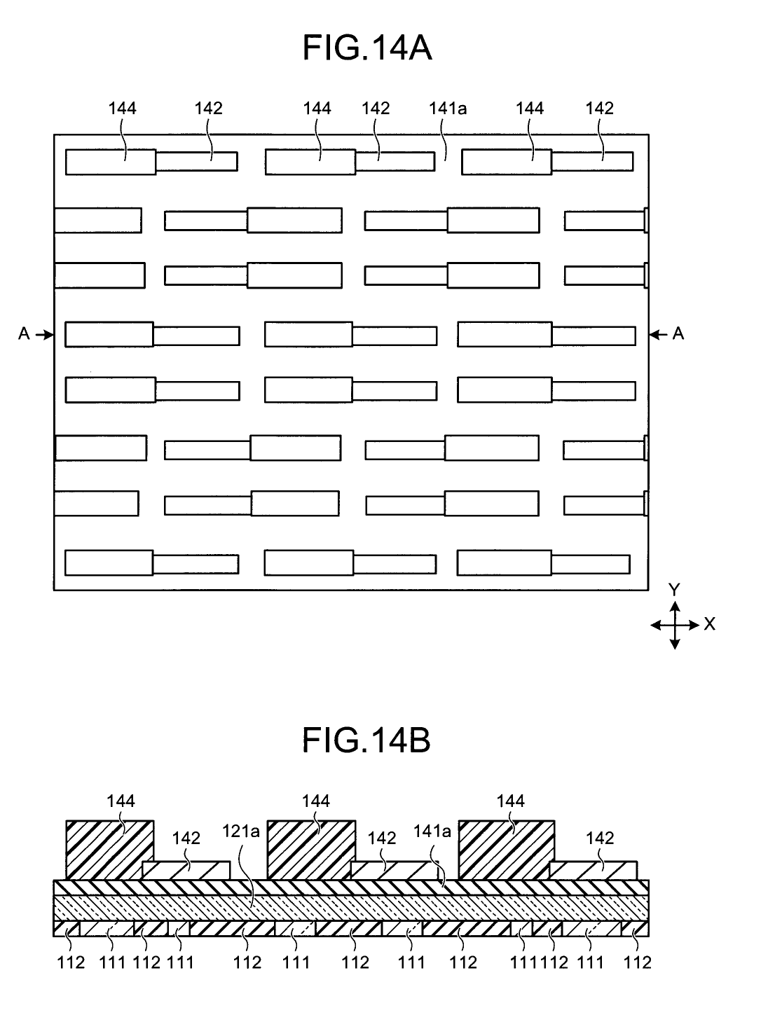

Next, by employing photolithography using the photomask for the gates B, second resist patterns 144 are formed at a position corresponding to the gates B 12 on the main surface of the semiconductor substrate, as shown in FIGS. 14A and 14B. The pattern of the photomask for the gates A and the pattern of the photomask for the gates B are so formed that the both patterns are overlapped each other in the longitudinal direction of the rectangular pattern by several tens of nanometers as shown in FIG. 4, and thus the second resist pattern 144 is so formed that one portion thereof is overlapped with the second hard mask pattern 142. Thereafter, according to need, a process of slimming the second resist patterns 144 are performed by etching.

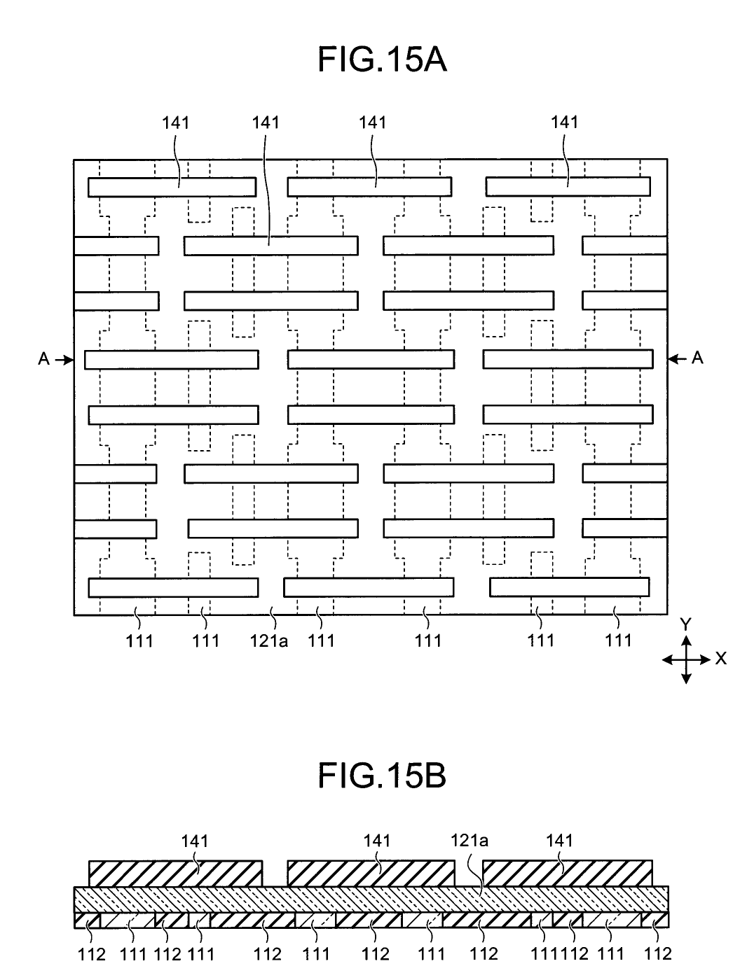

Next, the second hard mask patterns 142 and the second resist patterns 144 are used as a mask to etch the first hard mask film 141a, thereby forming a first hard mask patterns 141, as shown in FIGS. 15A and 15B. Thereby, the first hard mask patterns 141 are formed at a position corresponding to the gates A 11 and the gates B 12 on the main surface of the semiconductor substrate.

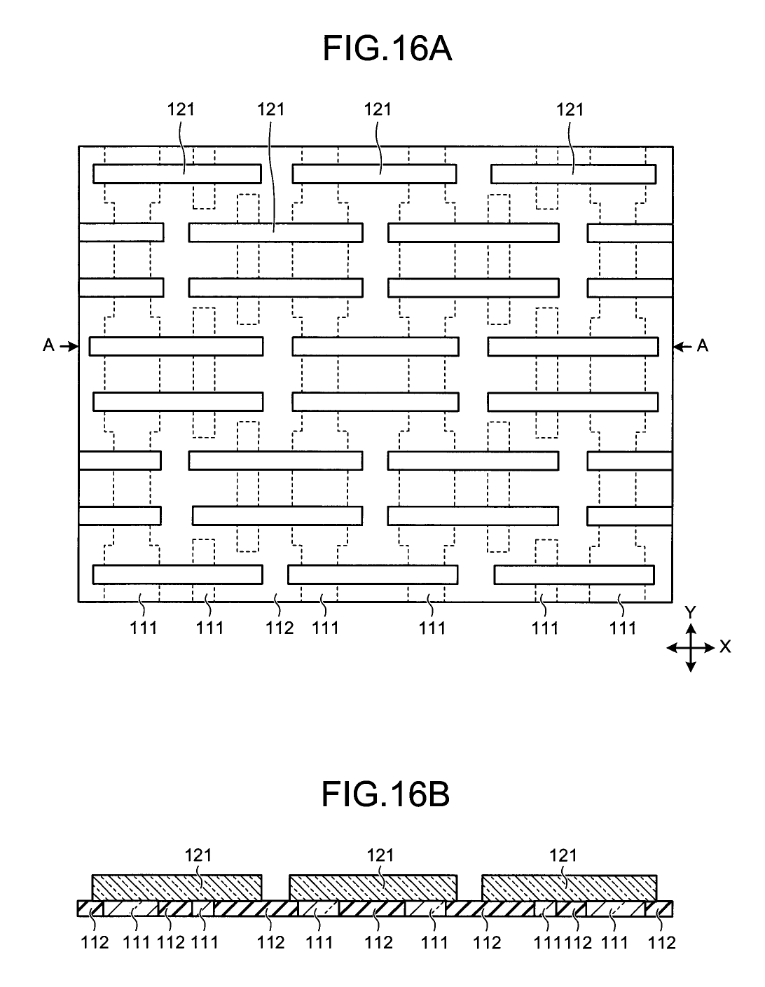

Next, the first hard mask patterns 141 are used as a mask to etch the polysilicon film 121a, thereby forming the gate electrodes 121, as shown in FIGS. 16A and 16B. Thereafter, steps after the formation of the interlayer insulating film 122 (FIGS. 10A and 10B) in the first embodiment are implemented. As a result, the highly-integrated SRAM shown in FIG. 1 can be formed.

Also in the highly-integrated SRAM manufacturing method according to the second embodiment, the same effect as that in the first embodiment can be obtained. That is, the length between the gate electrodes adjacent in the longitudinal direction and the length between the gate electrode and the contact hole can be shortened, and at the same time, these members can be formed at a desired position with a favorable positioning accuracy. Thus, area reduction of a semiconductor device can be achieved.

### Third Embodiment

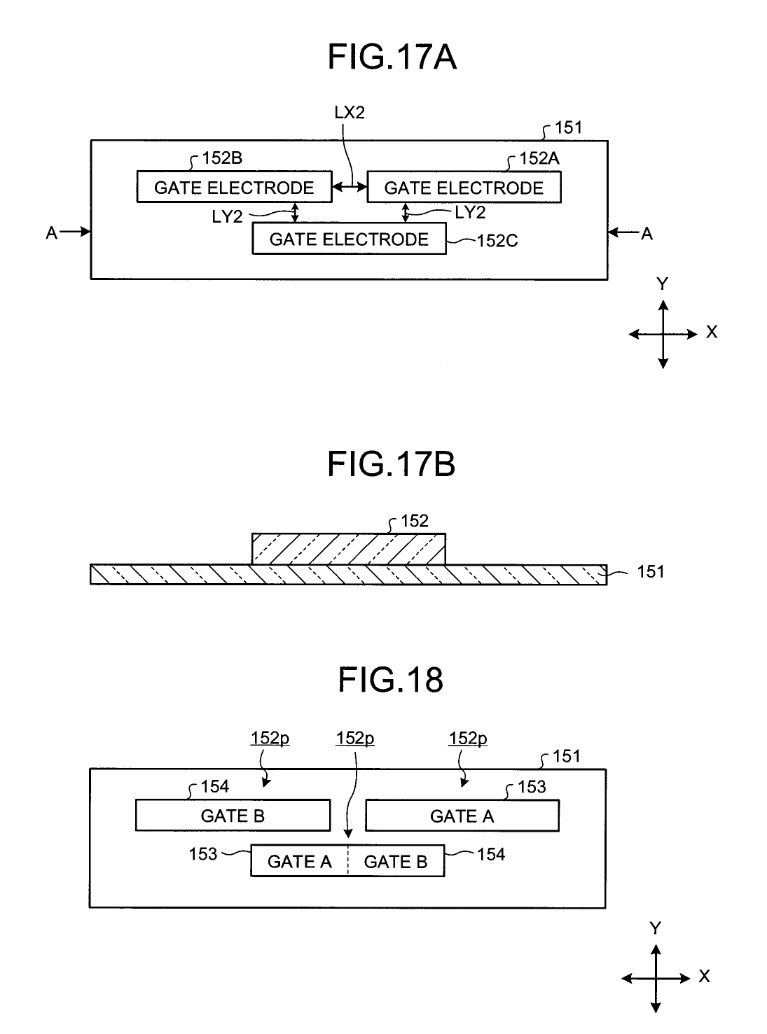

A third embodiment of the present invention describes a manufacturing method of a gate electrode in a semiconductor device. FIGS. 17A and 17B are schematic diagrams for explaining arrangement of a gate electrode 152 in the semiconductor device according to the third embodiment, where FIG. 17A is a plan view thereof, and FIG. 17B is a cross-sectional view thereof. In FIGS. 17A and 17B, a plurality of substantially rectangular gate electrodes 152 (a gate electrode 152A, a gate electrode 152B, and a gate electrode 152C) made of polysilicon are formed substantially parallel on a semiconductor substrate 151.

The gate electrode 152A and the gate electrode 152B are arranged on the substantially same line to be separated by a length LX2 in a longitudinal direction (an X direction in FIG. 17A. Hereinafter, “longitudinal direction”) of the gate electrode 152. The length LX2 is a length between the gate electrode 152A and the gate electrode 152B adjacent in the longitudinal direction (the X direction in FIG. 17A). The gate electrode 152C is arranged to be separated by a length LY2 in a lateral direction (a Y direction in FIG. 17A. Hereinafter, “lateral direction”) of the gate electrode 152 relative to the gate electrode 152A and the gate electrode 152B and also to be overlapped with each portion of the both gate electrode 152A and gate electrode 152B in the longitudinal direction (the X direction in FIG. 17A), for example, by the substantially same length. The length LY2 is a length between the gate electrode 152A and the gate electrode 152C and between the gate electrode 152B and the gate electrode 152C, adjacent in the lateral direction (the Y direction in FIG. 17A). Specifically, a gate insulating films are formed beneath the gate electrodes 152, and device forming regions and device isolating regions are formed on the semiconductor substrate 151. However, explanations of these constituent elements will be omitted.

In the third embodiment, the length LX2 is set to a very short length that exceeds the resolution limit of a photolithography technique, making it very difficult to form its configuration. Moreover, the length LY2 is set to a very short length that exceeds the resolution limit of a photolithography technique, making it very difficult to form its configuration. By having such a layout, the semiconductor device according to the third embodiment achieves high integration of transistors, thereby realizing a semiconductor device with a reduced area.

The manufacturing method of a gate electrode in the semiconductor device according to the third embodiment is described below with reference to FIGS. 18 to 22B. FIGS. 18 to 22B are schematic diagrams for explaining the manufacturing method of a gate electrode in the semiconductor device according to the third embodiment, where each drawing denoted with A is a plan view, and each drawing denoted with B is a cross-sectional view along a line A-A in each corresponding drawing denoted with A. Explanations of the formation of the gate insulating film will be omitted. First, as shown in FIG. 18, rectangular patterns 152p of the gate electrodes 152 are extracted from a design layout of the semiconductor device.

Next, in the extracted rectangular patterns 152p of the gate electrodes 152, the rectangular pattern 152p of the gate electrode 152A is used as a gate pattern A (hereinafter, “gate A”) 153 and the rectangular pattern 152p of the gate electrode 152B is used as a gate pattern B (hereinafter, “gate B”) 154. In this way, the design layout of the gate electrodes 152 is divided into two, that is, the gate A153 and the gate B154.

The gate electrode 152C is divided into two substantially rectangular patterns along a borderline of position that neither overlaps (opposes) the rectangular pattern 152p (gate A) of the gate electrode 152A nor the rectangular pattern 152p (gate B) of the gate electrode 152B in the longitudinal direction (an X direction in FIG. 18), and the two divided patterns are classified into the gate A153 and the gate B154 so that the patterns adjacent in the lateral direction (a Y direction in FIG. 18) are differed. That is, in the two divided patterns, in the lateral direction (the Y direction in FIG. 18), the rectangular pattern 152p of the gate electrode 152C at a position adjacent to the rectangular pattern 152p (gate A) of the gate electrode 152A is the gate B154, and the rectangular pattern 152p of the gate electrode 152C at a position adjacent to the rectangular pattern 152p (gate B) of the gate electrode 152B is the gate A153.

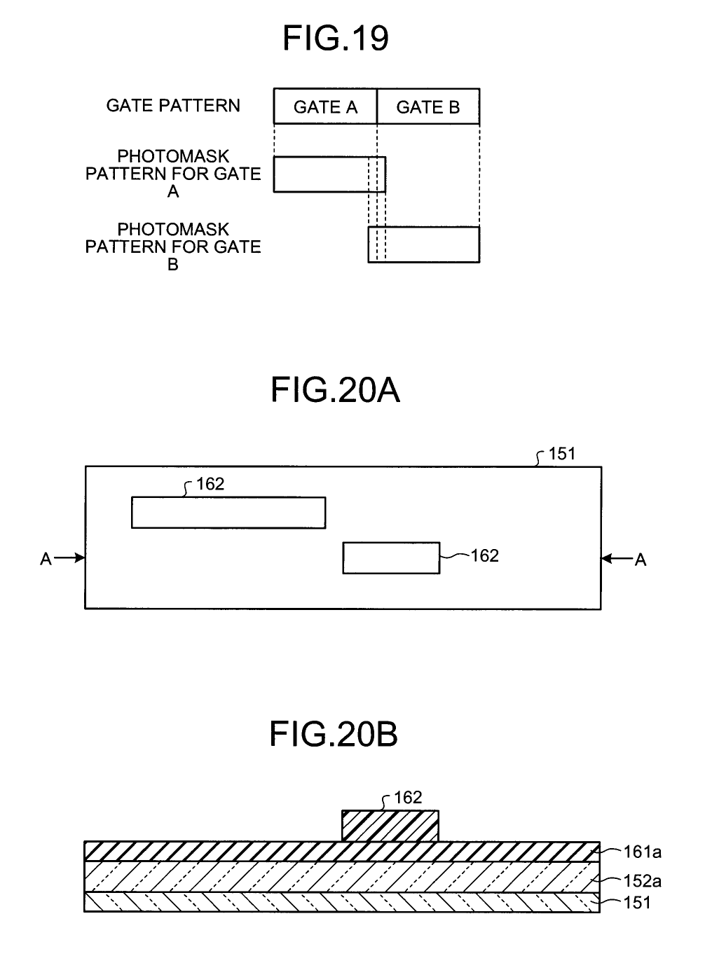

In order that in each of the classified layouts, the pattern according to the design value is formed on the semiconductor substrate, there is manufactured a photomask that is formed with a gate electrode pattern corrected by using OPC. That is, two photomasks (the photomask for the gate A and the photomask for the gate B) are manufactured. At this time, the patterns for the gate A and the gate B in the photomasks are so formed that the gate A153 and the gate B154 are overlapped each other by several tens of nanometers in the longitudinal direction, as shown in FIG. 19.

Next, as shown in FIGS. 20A and 20B, on the main surface of the semiconductor substrate 151, a polysilicon film 152a for forming a gate electrode is formed, and on top of it, a silicon nitride film, for example, is formed as a hard mask film 161a.

By employing photolithography using the photomask for the gate B, first resist patterns 162 is formed on the hard mask film 161a, as shown in FIGS. 20A and 20B. Thereby, the first resist patterns 162 is formed at a position corresponding to the gates B154 on the main surface of the semiconductor substrate 151. Thereafter, according to need, a process of slimming the first resist patterns 162 are performed by etching.

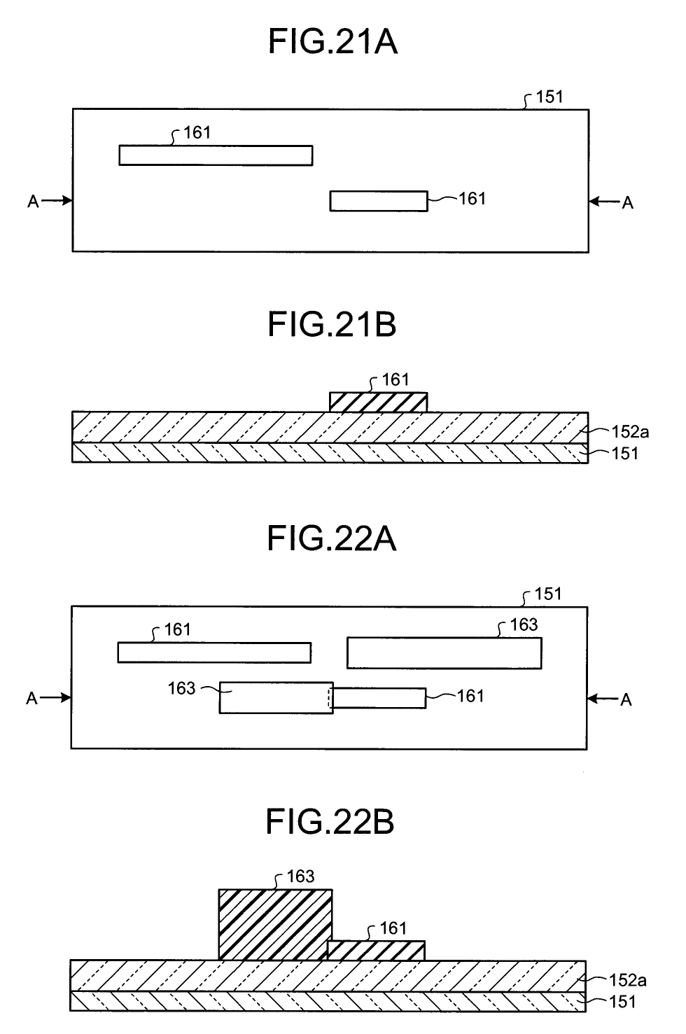

Next, the first resist patterns 162 are used as a mask to etch the hard mask film 161a, and as shown in FIGS. 21A and 21B, a hard mask pattern 161 is formed on the polysilicon film 152a. Thereby, the hard mask patterns 161 are formed at a position corresponding to the gate B154 on the main surface of the semiconductor substrate 151.

Next, by employing photolithography using the photomask for the gate A, second resist patterns 163 are formed at a position corresponding to the gate A153, as shown in FIGS. 22A and 22B. The pattern of the photomask for the gate A and the pattern of photomask for the gate B are so formed that the both patterns are overlapped each other in the longitudinal direction by several tens of nanometers, as shown in FIG. 19, and thus the second resist pattern 163 is so formed that one portion thereof is overlapped with the hard mask pattern 161. Thereafter, according to need, a process of slimming the second resist patterns 163 are performed by etching.

Next, the hard mask patterns 161 and the second resist patterns 163 are used as a mask to etch the polysilicon film 152a, thereby removing the hard mask patterns 161 and the second resist patterns 163. As a result, the gate electrode 152 can be formed as shown in FIGS. 17A and 17B.

As described above, in the manufacturing method of a gate electrode in the semiconductor device according to the third embodiment, at the time of forming the second resist patterns 163 for etching mask for forming the gate electrodes 152A and the hard mask patterns 161 for etching mask for forming the gate electrode 152B at a lithography step, the etching masks adjacent in the longitudinal direction are formed at different lithography steps. That is, the patterns of the gate electrodes 152 adjacent in the longitudinal direction are arranged, one pattern after the other, on the different photomasks, and transferred to the etching mask over two exposing steps. Thereby, even when the length LX2 between the gate electrodes 152 adjacent in the longitudinal direction exceeds the resolution limit of a photolithography technique, it is possible to prevent deterioration in the dimensional accuracy which is caused due to the length LX2 at the time of forming the etching mask and which is found in the exposure at a photolithography step, and possible to form a plurality of gate electrodes 152 with a favorable positioning accuracy at a desired position in the longitudinal direction. In the third embodiment, a case that the patterns for the gate electrodes 152 adjacent in the longitudinal direction are arranged, one pattern after the other, on the two respectively different photomasks, and transferred to the etching mask over the two exposing steps has been described. However, the patterns for the adjacent gate electrodes 152 can be separately arranged on a single photomask and transferred to the etching mask over the two exposing steps.

In another manufacturing method of a gate electrode in the semiconductor device according to the third embodiment, the etching mask for forming the gate electrode 152C is manufactured by being divided into the hard mask pattern 161 and the second resist pattern 163. At the time of forming the hard mask pattern 161 and the second resist pattern 163, a region in which the etching masks are overlapped in the longitudinal direction is formed at different lithography steps. Thereby, even when the length LY2 between the gate electrodes 152 adjacent in the lateral direction exceeds the resolution limit of a photolithography technique, it is possible to prevent deterioration in the dimensional accuracy which is caused due to the length LY2 and which is found in the exposure at a photolithography step, and possible to form a plurality of gate electrodes 152 with a favorable positioning accuracy at a desired position in the lateral direction.

In the third embodiment, in the photomask for the gates A and the photomask for the gates B, the patterns for the gate A and for the gate B are formed to be overlapped each other by several tens of nanometers in the longitudinal direction, and thus the second resist pattern 163 is so formed that one portion thereof is overlapped with the hard mask pattern 161. Thereby, at the time of forming the hard mask pattern 161 by using the photomask for the gates A, or at the time of forming the second resist pattern 163 by using the photomask for the gates B, even when slight positional deviation occurs in the longitudinal direction, the hard mask pattern 161 and the second resist pattern 163 are prevented from being separated from each other. That is, the separation of the mask pattern for forming the gate electrode 152C, which is caused due to the formation of the photomask for forming the gate electrode 152 at two different lithography steps, can be prevented, thereby forming the gate electrode 152C with a desired shape.

Accordingly, in the method of manufacturing a gate electrode in the semiconductor device according to the third embodiment, the length between the gate electrodes adjacent in the longitudinal direction and the lateral direction is shortened, and at the same time, these members can be formed at a desired position with a favorable positioning accuracy. Thus, area reduction of a semiconductor device can be achieved.

### Fourth Embodiment

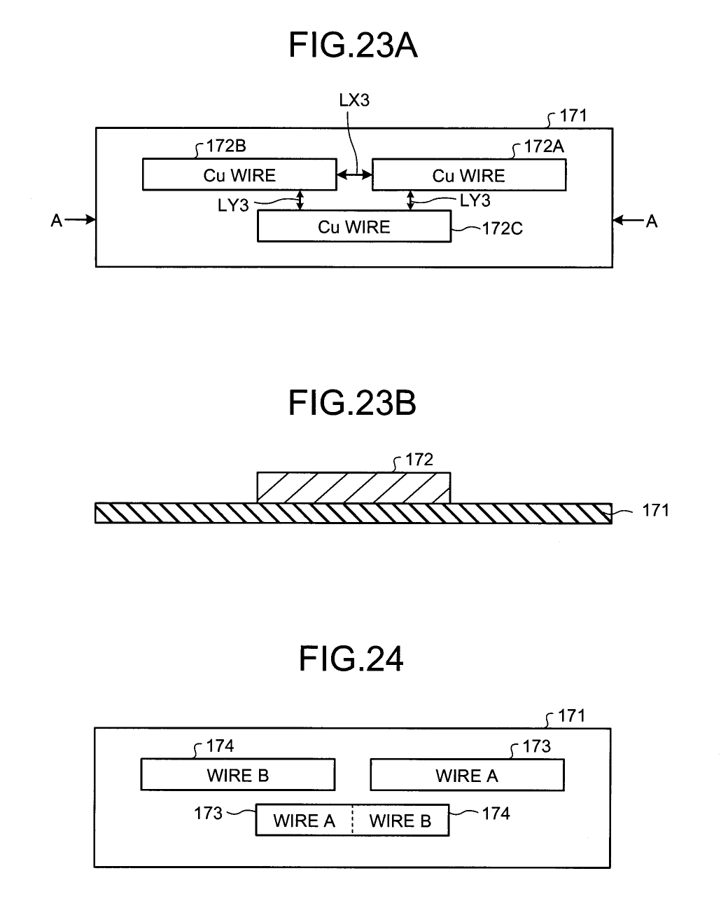

According to a fourth embodiment of the present invention, a manufacturing method of a wire layer in a semiconductor device will be described. FIGS. 23A and 23B are schematic diagrams for explaining arrangement of a wire layer in a semiconductor device according to the fourth embodiment, where FIG. 23A is a plan view thereof, and FIG. 23B is a cross-sectional view thereof. In FIGS. 23A and 23B, a plurality of substantially rectangular copper (Cu) wires 172 (a Cu wire 172A, a Cu wire 172B, and a Cu wire 172C) made of copper (Cu) are formed substantially parallel on an interlayer insulating film 171.

The Cu wire 172A and the Cu wire 172B are arranged on the substantially same line to be separated by a length LX3 in a longitudinal direction (an X direction in FIG. 23A. Hereinafter, “longitudinal direction”) of the Cu wire 172. The length LX3 is a length between the Cu wire 172A and the Cu wire 172B adjacent in the longitudinal direction (the X direction in FIG. 23A). The Cu wire 172C is so positioned that it is separated by a length LY3 in a lateral direction (a Y direction in FIG. 23A. Hereinafter, “lateral direction”) of the Cu wire 172 relative to the Cu wire 172A and the Cu wire 172B and that it is overlapped by the substantially same length only with respect to the Cu wire 172A and Cu wire 172B in the longitudinal direction (the X direction in FIG. 23A). The length LX3 is a length between the Cu wire 172A and the Cu wire 172C, and between the Cu wire 172B and the Cu wire 172C, adjacent in the lateral direction (the Y direction in FIG. 23A).

In the fourth embodiment, the length LX3 is set to a very short length that exceeds the resolution limit of a photolithography technique, making it very difficult to form its configuration. Moreover, the length LY3 is set to a very short length that exceeds the resolution limit of a photolithography technique, making it very difficult to form its configuration. By having such a layout, the semiconductor device according to the fourth embodiment enables high integration of transistors and area reduction.

A manufacturing method of the Cu wire 172 in a semiconductor device according to the fourth embodiment is described next. First, from the design layout of the semiconductor device, rectangular patterns for the Cu wires 172 are extracted. Subsequently, in the extracted rectangular pattern for the Cu wire 172, a rectangular pattern for the Cu wire 172A is a wire pattern A (Hereinafter, “wire A”) 173 and a rectangular pattern for the Cu wire 172B is a wire pattern B (Hereinafter, “wire B”) 174, as shown in FIG. 24. In this way, the design layout of the Cu wire 172 is classified into two, that is, the wire A 173 and the wire B 174.

Thereafter, when the same steps as those after FIG. 20 in the third embodiment are implemented, the (Cu) wires 172 (the Cu wire 172A, the Cu wire 172B, and the Cu wire 172C) can be formed. In this case, the wire A corresponds to the gate A and the wire B corresponds to the gate B. In the fourth embodiment, instead of the polysilicon film 152a, a Cu film is formed.

In the manufacturing method of a wire layer in the semiconductor device according to the fourth embodiment, at the time of forming the etching mask for forming the Cu wire 172A at a lithography step, the etching masks adjacent in the longitudinal direction are formed at different lithography steps. That is, the patterns for the Cu wires 172 adjacent in the longitudinal direction are arranged, one pattern after the other, on the different photomasks, and transferred to the etching mask over two exposing steps. Thereby, even when the length LX3 between the Cu wires 172 adjacent in the longitudinal direction exceeds the resolution limit of a photolithography technique, it is possible to prevent deterioration in the dimensional accuracy which is caused due to the length LY3 at the time of forming the etching mask and which is found in the exposure at a photolithography step, and possible to form a plurality of Cu wires 172 with a favorable positioning accuracy at a desired position in the longitudinal direction. In the fourth embodiment, a case that the patterns for the Cu wires 172 adjacent in the longitudinal direction are arranged, one pattern after the other, on the respectively different photomasks, and transferred to the etching mask over the two exposing steps has been described. However, the patterns for the adjacent Cu wires 172 can be separately arranged on a single photomask and transferred to the etching mask over the two exposing steps.

In another semiconductor device manufacturing method according to the fourth embodiment, the etching mask for forming the Cu wire 172C is manufactured in a divided manner. At the time of forming the etching mask, a region in which the etching masks are overlapped in the longitudinal direction is formed at different lithography steps. Thereby, even when the length LY3 between the Cu wires 172 adjacent in the lateral direction exceeds the resolution limit of a photolithography technique, it is possible to prevent deterioration in the dimensional accuracy which is caused due to the length LY3 and which is found in the exposure at a photolithography step, and possible to form a plurality of Cu wires 172 with a favorable positioning accuracy at a desired position in the lateral direction.

In the fourth embodiment, in the photomask for the wires A and the photomask for the wires B, the patterns for the wires A and for the wire B are formed to be overlapped each other by several tens of nanometers in the longitudinal direction. Thereby, the separation of the mask pattern for forming the Cu wire 172, which is caused due to the formation of the photomask for forming the Cu wires 172 at two different lithography steps, can be prevented, thereby forming Cu wire 172C with a desired shape.

Accordingly, in the method of manufacturing a wire layer in the semiconductor device according to the fourth embodiment, the length between wires adjacent in the longitudinal direction and the lateral direction is shortened, and at the same time, these members can be formed at a desired position with a favorable positioning accuracy. Thus, area reduction of a semiconductor device can be achieved.

Additional advantages and modifications will readily occur to those skilled in the art. Therefore, the invention in its broader aspects is not limited to the specific details and representative embodiments shown and described herein. Accordingly, various modifications may be made without departing from the spirit or scope of the general inventive concept as defined by the appended claims and their equivalents.

What is claimed is:

1. A manufacturing method of a semiconductor device including a semiconductor substrate that is formed thereon with:
a first constituent member;
a second constituent member that is extended to be separated from the first constituent member on an extension of a longitudinal direction of the first constituent member; and
a third constituent member that is separated from the first constituent member and the second constituent member in a lateral direction of the first and second constituent members and that is opposed in one portion to the first and second constituent members,
the manufacturing method comprising:
transferring simultaneously by lithography, a first region from a position opposed between the first and second constituent members in the longitudinal direction to an end of a side of the first constituent member in the longitudinal direction in the third constituent member, and a first mask pattern for forming the first constituent member, onto a semiconductor substrate;
transferring simultaneously by lithography a second region including regions other than the first region in the third constituent member and a second mask pattern for forming the second constituent member, onto the semiconductor substrate; and
forming the first constituent member, the second constituent member, and the third constituent member on the semiconductor substrate by using the first mask pattern and the second mask pattern.

2. The manufacturing method of a semiconductor device according to claim 1, wherein the second region overlaps with the first region at an end of a side of the second constituent member of the first region.

3. The manufacturing method of a semiconductor device according to claim 1, wherein the first mask pattern is a hard mask pattern and the second mask pattern is a resist pattern.

4. The manufacturing method of a semiconductor device according to claim 1, further comprising:
forming a third mask pattern on the semiconductor substrate by using the first mask pattern and the second mask pattern; and
forming the first constituent member, the second constituent member, and the third constituent member on the semiconductor substrate by using the third mask pattern.

5. The manufacturing method of a semiconductor device according to claim 4, wherein the first mask pattern is a hard mask pattern, the second mask pattern is a resist pattern, and the third mask pattern is a hard mask pattern.

6. The manufacturing method of a semiconductor device according to claim 1, wherein the first constituent member, the second constituent member, and the third constituent member are a gate electrode of a static random access memory.

7. The manufacturing method of a semiconductor device according to claim 1, wherein a length between the first constituent member and the second constituent member in the longitudinal direction is a length that exceeds a resolution limit of an exposure device used in the lithography.

8. A manufacturing method of a semiconductor device including a semiconductor substrate that is formed thereon with:
a first constituent member;
a second constituent member that is extended to be separated from the first constituent member on an extension of a longitudinal direction of the first constituent member;
a third constituent member that is separated from the first constituent member and the second constituent member in a lateral direction of the first and second constituent members and that is opposed in one portion to the first and second constituent members;
a first contact arranged to be separated from both the first constituent member and the third constituent member in a region between the first and third constituent members; and
a second contact arranged to be separated from both the second constituent member and the third constituent member in a region between the second and third constituent members,
the manufacturing method comprising:
transferring simultaneously by lithography, a first region from a position opposed between the first and second constituent members in the longitudinal direction to an end of a side of the first constituent member in the longitudinal direction in the third constituent member, and a first mask pattern for forming the first constituent member, onto a semiconductor substrate;
transferring simultaneously by lithography a second region including regions other than the first region in the third constituent member and a second mask pattern for forming the second constituent member, onto the semiconductor substrate;
forming the first constituent member, the second constituent member, and the third constituent member on the semiconductor substrate by using the first mask pattern and the second mask pattern;
forming by lithography a third mask pattern for forming the first contact on the semiconductor substrate by being aligned to the first constituent member and third constituent member;
forming by lithography a fourth mask pattern for forming the second contact on the semiconductor substrate by being aligned to the second constituent member and third constituent member; and
forming a contact hole for forming the first contact and a contact hole for forming the second contact on the semiconductor substrate by using the third mask pattern and the fourth mask pattern.

9. The manufacturing method of a semiconductor device according to claim 8, wherein the first constituent member, the second constituent member, and the third constituent member are a gate electrode of a static random access memory.

10. The manufacturing method of a semiconductor device according to claim 8, wherein a length between the first constituent member and the second constituent member in the longitudinal direction is a length that exceeds a resolution limit of an exposure device used in the lithography.

11. The manufacturing method of a semiconductor device according to claim 8, wherein the first mask pattern is a hard mask pattern and the second mask pattern is a resist pattern.

12. The manufacturing method of a semiconductor device according to claim 8, further comprising:
forming a fifth mask pattern on the semiconductor substrate by using the first mask pattern and the second mask pattern; and
forming the first constituent member, the second constituent member, and the third constituent member on the semiconductor substrate by using the fifth mask pattern.

13. The manufacturing method of a semiconductor device according to claim 12, wherein the first mask pattern is a hard mask pattern, the second mask pattern is a resist pattern, and the third mask pattern is a hard mask pattern.

14. A manufacturing method of a semiconductor device including a semiconductor substrate that is formed thereon with:
a first constituent member;
a second constituent member that is extended to be separated from the first constituent member on an extension of a longitudinal direction of the first constituent member; and
a third constituent member that is separated from the first constituent member and the second constituent member in a lateral direction of the first and second constituent members and that is opposed in one portion to the first and second constituent members,
the manufacturing method comprising:
transferring simultaneously by lithography, a first region from a position opposed between the first and second constituent members in the longitudinal direction to an end of a side of the second constituent member in the longitudinal direction in the third constituent member, and a first mask pattern for forming the first constituent member, onto a semiconductor substrate;
transferring simultaneously by lithography a second region including regions other than the first region in the third constituent member and a second mask pattern for forming the second constituent member, onto the semiconductor substrate; and
forming the first constituent member, the second constituent member, and the third constituent member on the semiconductor substrate by using the first mask pattern and the second mask pattern.

15. The manufacturing method of a semiconductor device according to claim 14, wherein the second region overlaps with the first region at an end of a side of the first constituent member of the first region.

16. The manufacturing method of a semiconductor device according to claim 14, wherein the first constituent member, the second constituent member, and the third constituent member are a gate electrode.

17. The manufacturing method of a semiconductor device according to claim 14, wherein the first constituent member, the second constituent member, and the third constituent member are a wire.

18. The manufacturing method of a semiconductor device according to claim 14, wherein a length between the first constituent member and the second constituent member in the longitudinal direction is a length that exceeds a resolution limit of an exposure device used in the lithography.
